(19) United States
(12) Patent Application Publication
(10) Pub. No.: US 2012/0288968 A1
(43) Pub. Date: Nov. 15, 2012

(54) Method for repairing a semiconductor structure having a current-leakage issue

(76) Inventors: Ming-Teng Hsieh, New Taipei City (TW); Yi-Nan Chen, Taipei City (TW); Hsien-Wen Liu, Taoyuan County (TW)

(21) Appl. No.: 13/106,837

(22) Filed: May 12, 2011

(51) Int. Cl. H01L 21/66

(52) U.S. Cl. 438/4; 438/17; 257/E21.525

(57) ABSTRACT

A method for repairing a semiconductor structure having a current-leakage issue includes finding a semiconductor structure having a current-leakage issue through application of a test voltage from an electric test device and applying an electric power stress to the semiconductor structure to melt a stringer or a bridge between two conductive elements or to allow the stringer or the bridge to be oxidized.

### BACKGROUND OF THE INVENTION

1. Field of the Invention

The present invention relates to semiconductor device fabrication, and particularly to repairing of semiconductor structure having defects in electric properties.

2. Description of the Prior Art

After a semiconductor structure is fabricated, it may be subject to a current leakage test and found out to have a current leakage problem. Current leakage may arise from a defect existing in the semiconductor structure. For example, when a conductive element is formed through processes, such as etching, deposition, epitaxial growth, annealing, or the like, a stringer or a bridge may be formed to be extended from the conductive element into a dielectric layer. The “stringer” usually means a silk-shaped or string-shaped protrusion, or the like, protruding from the conductive element. For example, tungsten (W) is usually used to fill trenches for forming word lines through a chemical vapor deposition, in which, source gasses, WF₆ and H₂, react to form tungsten and hydrogen fluoride (HF). The byproduct HF is corrosive to silicon oxide. If liner (usually including TiN) on the trenches is not well formed, HF may corrode the silicon oxide sidewall or bottom of the trenches to form a deep small hole. When tungsten atoms are deposited on the sidewall or bottom of the trench, the deep hole is also filled with the tungsten atoms to become the so-called stringer. The “bridge” usually means a post-shaped, cone-shaped, wedge-shaped, sheet-shaped or plate-shaped protrusion, or the like, protruding from the conductive element. When the stringer or the bridge is very close to or contact another conductive element, an unwanted current may flow between these two conductive elements through the stringer or the bridge during operation of the semiconductor structure, causing a current-leakage issue. When the current leakage is serious, it may cause a short circuit, or other problem.

Conventionally, a semiconductor structure after formed is tested for electric properties. Since rework of the wafer is not economic and there is no repairing solution for the current-leakage issue, the semiconductor structure product having the current-leakage issue is just thrown away.

Therefore, there is still a need for a novel method to repair a semiconductor structure having a current-leakage issue.

### SUMMARY OF THE INVENTION

An objective of the present invention is to provide a method for repairing a semiconductor structure having a current-leakage issue, such that the semiconductor structure can be economically repaired.

According to one embodiment of the present invention, a method for repairing a semiconductor structure having a current-leakage issue includes steps as follows. A semiconductor structure having a current-leakage issue is found through application of a test voltage by utilizing an electric test device. An electric power stress is applied to the semiconductor structure to melt a stringer or abridge between two conductive elements of the semiconductor structure or to allow the stringer or the bridge to be oxidized.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 3 are schematic diagrams showing a bridge existing among conductive elements and illustrating the repairing method according to one embodiment of the present invention;

FIGS. 4 to 6 are schematic diagrams showing a bridge existing between conductive elements and illustrating the repairing method according to another embodiment of the present invention; and

FIGS. 7 to 9 are schematic diagrams showing a stringer existing between conductive elements and illustrating the repairing method according to still another embodiment of the present invention.

### DETAILED DESCRIPTION

After a semiconductor structure is obtained as a product from a fabrication process, it may be subject to a current leakage test and found out to have a current leakage issue. This semiconductor structure may be repaired using the method according to the present invention. According to one embodiment of the present invention, the method for repairing a semiconductor structure having a current-leakage issue includes steps as follows. A semiconductor structure having a current-leakage issue is found through application of a test voltage from an electric test device. The semiconductor structure may include an integrated electric circuit. For example, it may be a memory structure, such as RAM, ROM, and flash memory, a power structure, an optical sensor, or the like, but not limited thereto. The current leakage test may be carried out in a conventional way. In detail, the semiconductor structure is tested by application of an electric power stress (or an electric current) which is provided by an electric test device, so as to find out if it has a current leakage issue. The electric test device may be a conventional one, and the magnitude (also referred to as “value”) of the electric power stress applied to the semiconductor structure may be within the range which is usable for a current leakage test in accordance with the specification, description, or direction of the electric test device and the semiconductor structure to be tested, or under a normal test conditions. One embodiment for the electric power stress is 1.5 volts, but not limited thereto.

If a semiconductor structure is found out to have a current leakage issue, the current leakage issue may arise from a structure defect, such as a stringer or bridge existing among or between two conductive elements. The stringer or bridge may be the same material as one of the two conductive elements and formed to protrude therefrom. The conductive elements may include metal, such as tungsten, aluminum, copper and the like, or polysilicon. An electric power stress is applied to the semiconductor structure to melt the stringer or bridge or to allow the stringer or bridge to be oxidized. Application of the electric power stress may allow the conductive elements, including the stringer or bridge, to be heated due to electric resistance. As the work (w) produced through application of the electric power stress relates to the multiple of current, resistance and time and the work will turn into heat, greater resistance will result in a greater amount of heat under the same current and the same time period. Since the stringer or bridge is tiny relative to the conductive elements, the stringer or bridge has a small cross-sectional area and accordingly has a relatively high resistance. The heat produced through the application of the electric power stress may be sufficient to melt the stringer or bridge or to allow the stringer or bridge to be oxidized. When the stringer or bridge is melted, its front tends to draw back, and such that the distance from the front of the stringer or bridge to another conductive element can be increased. Accordingly, the current leakage will not occur due to the increased distance. Alternatively, the stringer or bridge may be melted to break, so as to prevent from the current leakage.

Alternatively, as the stringer or bridge is heated by the electric power stress, it tends to react with oxygen or oxide existing within the semiconductor structure, for example a dielectric layer containing oxygen, such as various silicon oxide compounds, and borophosphosilicate glass (BPSG), and becomes oxidized as an oxide. When the stringer or bridge is oxidized, it becomes electric non-conductive, and, accordingly, the current leakage through the stringer or bridge may not occur. Without being bound to the theory, for example, when the stringer or bridge includes tungsten (W) and is heated upon the application of the test voltage, the tungsten may bond with the oxygen of silicon oxide to form tungsten oxide.

The electric power stress for application to repair the semiconductor structure may be just in a range of magnitude usable for a current-leakage test. Accordingly, the electric power stress will not be harmful to the elements in the semiconductor structure other than the stringer or the bridge. The electric power stress may be conveniently provided by the electric test device which provides the test voltage to test the semiconductor structure for the electric properties, but not limited thereto, and applied to the semiconductor structure in the same way as the test voltage is applied to the semiconductor substrate. The electric power stress may be greater than the test voltage, or the electric power stress may be provided for a plurality of times to the semiconductor structure, so as to provide more energy than the test voltage to the semiconductor structure for melt the stringer or bridge or for the oxidation, as long as it is not harmful to the semiconductor structure.

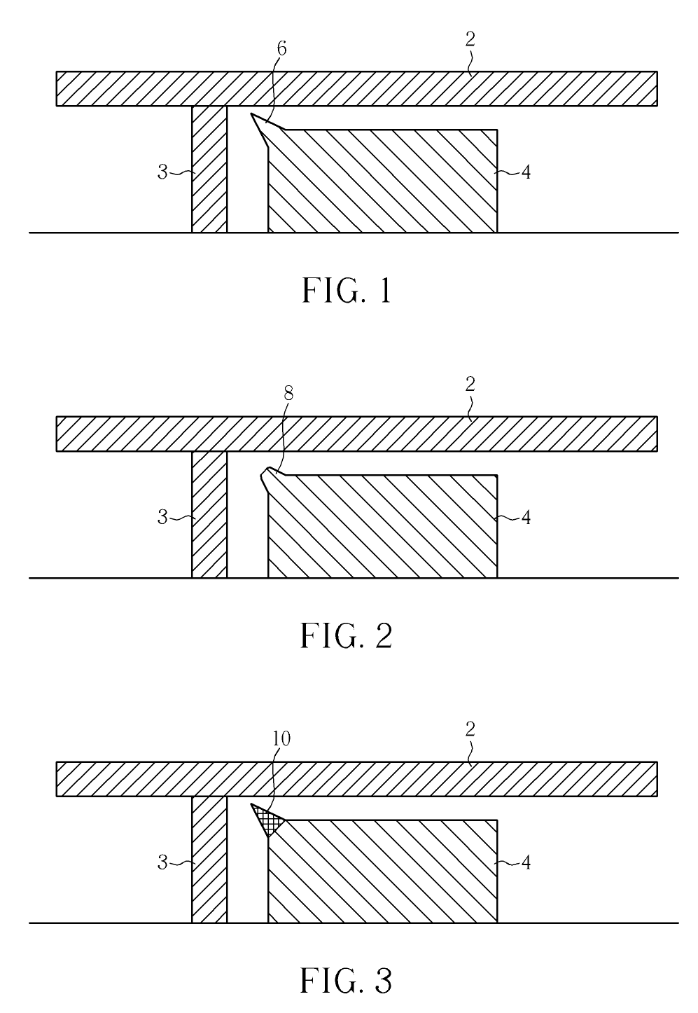

FIGS. 1 to 3 illustrate one embodiment according to the present invention. The semiconductor structure includes conductive elements, such as a bit line 2, a bit line contact 3, and a word line 4. Abridge 6 grows to protrude from the word line 4 and nearly touches or has touched the bit line 2 with its sharp front. The semiconductor structure is tested through application of a test voltage for the electric properties and found to have a current-leakage issue. The semiconductor structure is thereafter applied with an electric power stress, so as to melt the bridge 6 to become a protrusion 8 with a drawn-back front, as shown in FIG. 2, or to allow the bridge 6 to be oxidized to become an oxide bridge 10, as shown in FIG. 3. Accordingly, the semiconductor structure is repaired and can serve without current-leakage problems.

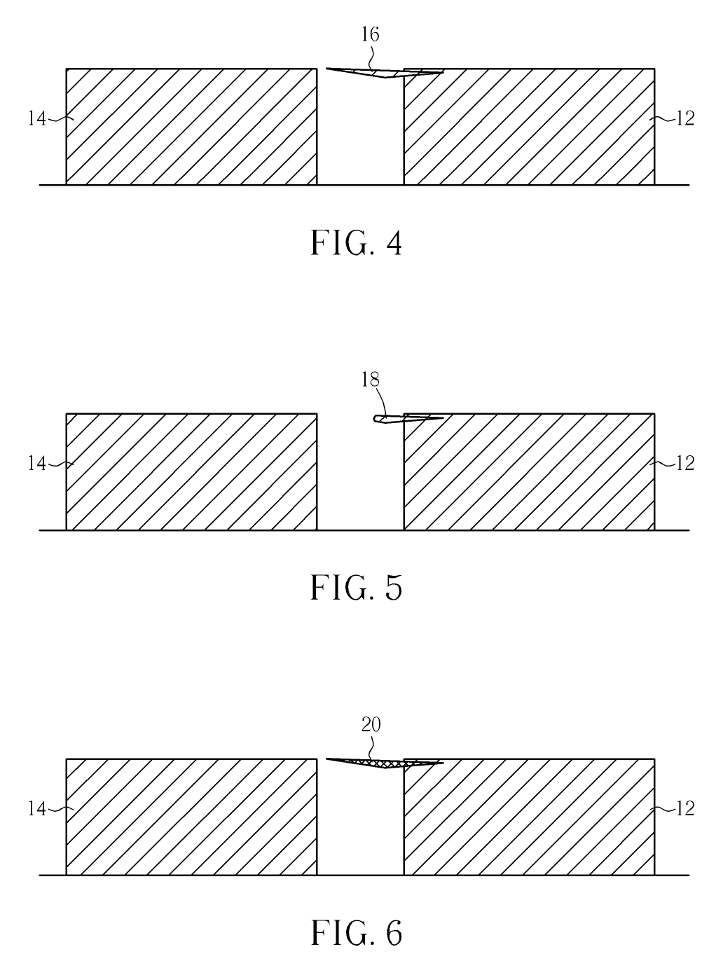

FIGS. 4 to 6 illustrate another embodiment according to the present invention. As shown in FIG. 4, the semiconductor structure found to have a current-leakage issue includes conductive elements 12 and 14. Abridge 16 grows to protrude from the conductive element 12 and nearly touches or has touched the conductive element 14 with its sharp front. The semiconductor structure is thereafter applied with an electric power stress, so as to melt the bridge 16 to become a protrusion 18 with a drawn-back front, as shown in FIG. 5, or to allow the bridge 16 to be oxidized to become an oxide bridge 20, as shown in FIG. 6. Accordingly, the semiconductor structure is repaired and can serve without current-leakage problems.

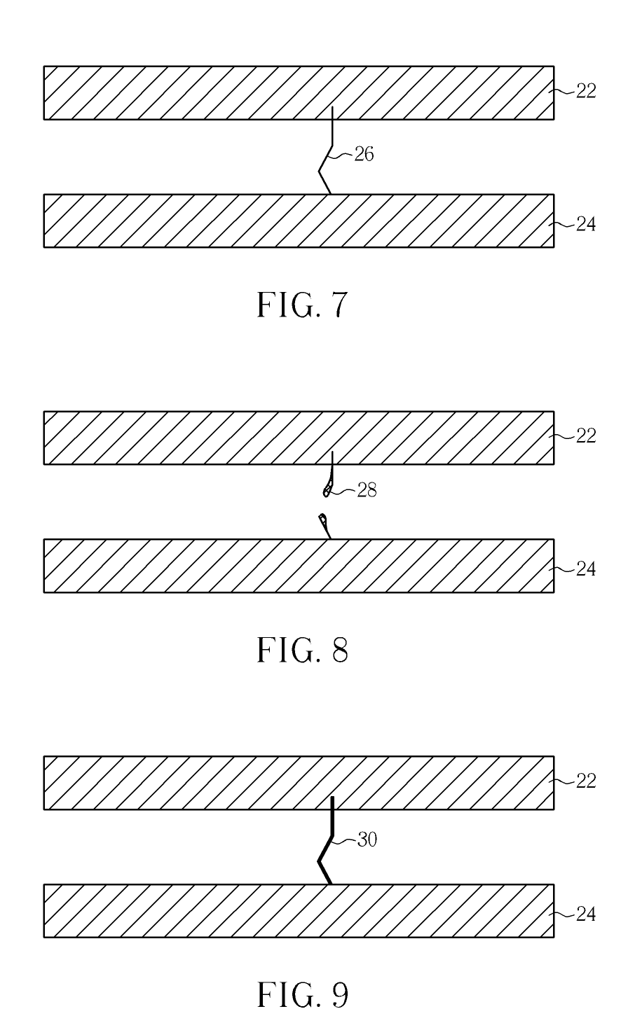

FIGS. 7 to 9 illustrate further another embodiment according to the present invention. As shown in FIG. 7, the semiconductor structure found to have a current-leakage issue includes metal lines 22 and 24. A stringer 26 grows from the metal line 22 and connects with the metal line 24. The semiconductor structure is thereafter applied with an electric power stress, so as to melt the stringer 26 to become a broken stringer 28, as shown in FIG. 8, or to allow the stringer 26 to be oxidized to become an oxide stringer 30, as shown in FIG. 9. Accordingly, the semiconductor structure is repaired and can serve without current-leakage problems.

In the present invention, an electric power stress is applied to a semiconductor structure having a current-leakage issue to provide heat for melting or oxidizing a stringer or a bridge, to prevent from current leakage. Especially, in one embodiment, it is more convenient that the electric power stress can be just as great as one in a range of voltage (or current) normally utilized for an electric properties test and applied, in the same way as the test voltage is applied, to the semiconductor structure for a plurality of times for providing sufficient heat.

Those skilled in the art will readily observe that numerous modifications and alterations of the device and method may be made while retaining the teachings of the invention.

What is claimed is:

1. A method for repairing a semiconductor structure having a current-leakage issue, comprising:
finding a semiconductor structure having a current-leakage issue through application of a test voltage by utilizing an electric test device; and
applying an electric power stress to the semiconductor structure to melt a stringer or a bridge between two conductive elements of the semiconductor structure or to allow the stringer or the bridge to be oxidized.

2. The method for repairing a semiconductor structure having a current-leakage issue according to claim 1, wherein the electric power stress is in a range of magnitude usable for a current-leakage test.

3. The method for repairing a semiconductor structure having a current-leakage issue according to claim 2, wherein the electric power stress is from the electric test device.

4. The method for repairing a semiconductor structure having a current-leakage issue according to claim 3, wherein the electric power stress is greater than the test voltage.

5. The method for repairing a semiconductor structure having a current-leakage issue according to claim 3, wherein the electric power stress is applied to the semiconductor structure for a plurality of times.

6. The method for repairing a semiconductor structure having a current-leakage issue according to claim 4, wherein the electric power stress is applied to the semiconductor structure for a plurality of times.

7. The method for repairing a semiconductor structure having a current-leakage issue according to claim 2, wherein the electric power stress is greater than the test voltage.

8. The method for repairing a semiconductor structure having a current-leakage issue according to claim 2, wherein the electric power stress is applied to the semiconductor structure for a plurality of times.

9. The method for repairing a semiconductor structure having a current-leakage issue according to claim 7, wherein the electric power stress is applied to the semiconductor structure for a plurality of times.

10. The method for repairing a semiconductor structure having a current-leakage issue according to claim 2, wherein the electric power stress is from the electric test device.

11. The method for repairing a semiconductor structure having a current-leakage issue according to claim 10, wherein the electric power stress is greater than the test voltage.

12. The method for repairing a semiconductor structure having a current-leakage issue according to claim 10, wherein the electric power stress is applied to the semiconductor structure for a plurality of times.

13. The method for repairing a semiconductor structure having a current-leakage issue according to claim 11, wherein the electric power stress is applied to the semiconductor structure for a plurality of times.

14. The method for repairing a semiconductor structure having a current-leakage issue according to claim 1, wherein the electric power stress is greater than the test voltage.

15. The method for repairing a semiconductor structure having a current-leakage issue according to claim 1, wherein the electric power stress is applied to the semiconductor structure for a plurality of times.

16. The method for repairing a semiconductor structure having a current-leakage issue according to claim 15, wherein the electric power stress is applied to the semiconductor structure for a plurality of times.
